(19) United States
(12) Patent Application Publication
(10) Pub. No.: US 2024/0243547 A1
(43) Pub. Date: Jul. 18, 2024

(54) DRIVER CIRCUIT AND METHOD FOR A SEMICONDUCTOR LASER

(71) Applicant: Streamlight, Inc., Eagleville, PA (US)

(72) Inventor: Jon C. Zeisler, Audubon, PA (US)

(21) Appl. No.: 18/409,324

(22) Filed: Jan. 10, 2024

Related U.S. Application Data
(60) Provisional application No. 63/438,834, filed on Jan. 13, 2023.

(51) Int. Cl. H01S 5/042

(52) U.S. Cl. CPC H01S 5/0428

(57) ABSTRACT

A driver circuit may comprise: a power control converts input power to an output voltage; a high frequency switch provides short duration pulses of output voltage causing a pulsed load current to flow through a load; a current sensor generates a signal representative of the pulsed load current; a sample and hold circuit samples the signal representative of the pulsed load current in synchronism with the high frequency switch and holds the sampled signal value; and a controller responds to the sampled signal value and applies control signals to the power control to produce the desired output voltage and to the high frequency switch and the sample and hold circuit to control the pulsed load current to a predetermined value. A corresponding method and an efficiency improver are disclosed. The load may include: a semiconductor laser diode (e.g., a green or blue semiconductor laser diode), or a light emitting diode.

This application claims the benefit and priority of U.S. Provisional Application No. 63/438,834 filed Jan. 13, 2023, and entitled “DRIVER CIRCUIT FOR A SEMICONDUCTOR LASER,” which is hereby incorporated herein by reference in its entirety for all purposes.

The present invention relates to a driver circuit and, in particular, to a driver circuit for a load or a semiconductor laser and a method therefor.

Semiconductor lasers are widely employed in various electronic devices including, e.g., flashlights, firearm aiming lights, laser pointers, industrial tools, and the like. For each device the output power of the laser, both peak power and average power, must be limited for safety, e.g., eye safety and/or safety from causing burns. Often light-producing semiconductor diodes are operated at a high current whereat they exhibit a higher efficiency for short periods of time such that the low duty cycle (ratio of ON time to the total time of a period of the drive signal, e.g., current) reduces the average output power level to be within the applicable safety limits.

Conventional semiconductor laser drive circuits typically operate in a relatively low range of pulse frequencies, e.g., from continuous wave (CW) up to a few KHz, whereat conventional drive circuits are capable of providing pulsed drive currents that are adequately controllable within applicable safe power levels. Those drive circuits cannot be operated at higher pulse frequencies, e.g., at or above about 55 KHz, whereat they cannot properly control the peak and average current levels, and thus the peak and average laser output power, to remain within safe limits.

The United States Food and Drug Administration (FDA) has established rules governing the operation of laser diodes so that their output power are within safe limits for protecting people who may be illuminated by the laser light therefrom from injury. Of interest are devices that output a beam of laser light into spaces where people may be illuminated, such as laser pointers, certain industrial tools, and firearm aiming lights. The FDA places these devices into classes according to their output power; in that FDA class structure, Class IIIa permits a maximum average output power of 5 milliwatts (mW) when the period of the pulse train is 18 usec or less, e.g., a frequency of 55 KHz or higher. Sec, ANSI Z136.1-2007, “American National Standard for Safe Use of Lasers.”

Applicant believes there is a need for semiconductor laser drive circuit that can operate at a high frequency, e.g., at or above 55 KHz, and at a higher efficiency whereby battery runtime may be extended or a battery having a smaller ampere-hour capacity may be employed. Applicant also believes that additionally or alternatively, there may be a need for a driver circuit that operates to provide pulsed power to a load at a relatively high frequency or pulse rate whereat the duration of the pulses of power are of very short duration.

Accordingly, a driver circuit may comprise: a power control converts input power to an output voltage; a high frequency switch provides short duration pulses of output voltage to a load causing a pulsed load current to flow therethrough; a current sensor generates a signal representative of the pulsed load current; a sample and hold circuit samples the signal representative of the pulsed load current in synchronism with the high frequency switch and holds the sampled signal value; and a controller responds to the sampled signal value and a reference value, and applies control signals to the power control to produce the desired output voltage, and to the high frequency switch and the sample and hold circuit to control the pulsed load current to a predetermined value. The load may include: a light producing semiconductor device, a semiconductor laser diode; a green semiconductor laser diode; or a blue semiconductor laser diode; or a light emitting diode.

A method for supplying pulses of electrical power to a load may comprise: converting an input power to an output voltage; providing or applying high frequency short duration pulses of the output voltage to a load causing a pulsed load current of like duration to flow therethrough; sensing the pulsed load current flow for generating a signal representative of the pulsed load current; sampling the signal representative of the pulsed load current in synchronism with the high frequency short duration pulses and holding the sampled signal value; and receiving the sampled signal value and a reference value, and applying control signals responsive to the sampled signal value and to the reference value to produce a desired output voltage and to control the high frequency short duration pulses and the sampling and holding to control the pulses of electrical power to a predetermined value. The load may include: a light producing semiconductor device, a semiconductor laser diode; a green semiconductor laser diode; or a blue semiconductor laser diode; or a light emitting diode.

In summarizing the arrangements described and/or claimed herein, a selection of concepts and/or elements and/or steps that are described in the detailed description herein may be made or simplified. Any summary is not intended to identify key features, elements and/or steps, or essential features, elements and/or steps, relating to the claimed subject matter, and so are not intended to be limiting and should not be construed to be limiting of or defining of the scope and breadth of the claimed subject matter.

### BRIEF DESCRIPTION OF THE DRAWING

The detailed description of the preferred embodiment(s) will be more easily and better understood when read in conjunction with the FIGURES of the Drawing which include:

FIG. 1 is a schematic block diagram of an example embodiment of a light including a semiconductor laser and driver circuit;

FIG. 2 is a schematic circuit diagram of an example embodiment of an example embodiment of a driver circuit for a semiconductor laser;

FIG. 3 is a graphical representation illustrating certain parameters relating to an example semiconductor laser;

FIG. 4 is a graphical representation of the optical power output versus the forward current of an example semiconductor laser;

FIG. 5 is a graphical representation of the input power and forward voltage for an example semiconductor laser at various temperatures, and

FIG. 6 is a schematic diagram of a process for further increasing the operating efficiency of an example semiconductor laser in an example driver circuit as described herein.

In the Drawing, where an element or feature is shown in more than one drawing figure, the same alphanumeric designation may be used to designate such element or feature in each figure, and where a closely related or modified element is shown in a figure, the same alphanumerical designation may be primed or designated “a” or “b” or the like to designate the modified element or feature. Similar elements or features may be designated by like alphanumeric designations in different figures of the Drawing and with similar nomenclature in the specification. As is common, the various features of the drawing are not to scale, the dimensions of the various features may be arbitrarily expanded or reduced for clarity, and any value stated in any Figure is by way of example only.

### DESCRIPTION OF THE PREFERRED EMBODIMENT(S)

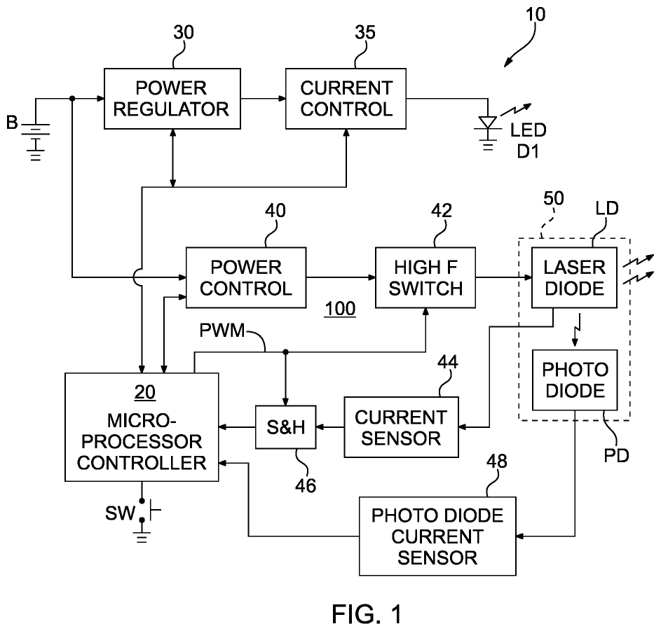

FIG. 1 is a schematic block diagram of an example embodiment of a light including a semiconductor laser and a driver circuit. Example light 10 includes an electronic circuit 100 for operating a semiconductor laser 50 and optionally a light emitting diode (LED). Example light 10 includes an LED D1 that produces visible light over a range of wavelengths in the visible spectrum and a semiconductor laser 50 including a laser diode LD which emits light substantially at a single wavelength (or over a very narrow band of wavelengths) and a photo diode PD that is responsive to the laser light emitted from laser diode LD. Electrical power for light 10 is provided from, e.g., a battery B.

LED D1 is energized via power regulator 30 which receives electrical power from battery B and changes the voltage thereof to a level suitable for energizing LED D1. Current control 35 receives electrical power from regulator 30 and applies electrical power to LED D1, preferably at a desired level of current because the light output of LED D1 is more closely related to the current applied thereto than to the voltage across its terminals which is sensitive to inter alia temperature. Typically, LED D1 may be a white LED for general illumination, or may be a colored LED, e.g., producing red or green or blue or infrared (IR) or ultraviolet (UV) light, as might be desirable for particular applications of light 10.

Microprocessor controller 20 may be referred to as microcontroller 20, microprocessor 20, controller 20 or as processor 20, and includes both digital and analog capabilities. Microprocessor controller 20 receives inputs from a control device of light 10, typically an electrical switch SW for controlling the operation of light 10 in accordance with a user's commands inputted via actuating the switch, e.g., to turn LED D1 ON and OFF, and/or to change the brightness level thereof, and the like. When commanded to operate LED D1, controller 20 provides control signals to and receives feedback signals from power regulator 30 and current control 35 for controlling the voltage produced by regulator 30 and the current applied by control 35 to energize LED D1 to the level indicated by the commands it receives.

Electronic circuit 100 includes a semiconductor laser drive circuit including controller 20, power control 40, high frequency switch 42, LD current sensor 44, sample and hold 46, and photo diode current sensor 48 for operating semiconductor laser 50 which includes a laser diode LD and a photo diode PD. In an example embodiment, high frequency switch 42, laser diode LD and current sensor 44 are effectively connected in series for simplicity in directly controlling and measuring the current flowing through laser diode LD. However, the order in which these elements are connected in series can vary as may facilitate operation with the remainder of electronic circuit 100 in any particular embodiment.

Semiconductor laser 50 includes a semiconductor laser diode LD that is energized via power control 40 which receives electrical power from battery B and changes the voltage thereof to a level suitable for energizing laser diode LD. High frequency switch 42 receives electrical power from power control 40 and is operated periodically to apply short pulses of that electrical power to laser diode LD, preferably to cause a desired level of laser diode LD current, because the laser light output of laser diode LD is more closely related to the current applied thereto, whether applied continuously or pulsed, than to the voltage across its terminals.

Current sensor 44 provides a signal proportional to the current flowing through laser diode LD and the output signal from current sensor 44 is sampled and held by sample and hold circuit 46 which samples the output signal synchronously with the pulses of current that flow through laser diode LD, thereby to provide a continuous representation of the magnitude of these current pulses.

When commanded to operate laser diode LD, digital controller 20 provides control signals to power control 40, a pulse width modulated (PWM) switching signal to high frequency switch 42 and sample and hold circuit 46, and receives feedback signals from current sensor 44 via sample and hold circuit 46, which represent voltages and/or currents thereof. Controller 20 thus controls the voltage produced by power control 40 and the magnitude, duration and frequency of the pulses of current ILD applied by high frequency switch 42 to energize laser diode LD to the current level indicated by the commands it receives. In some embodiments, controller 20 may also receive feedback signals from power control 40 for directly controlling the output voltage VLD thereof.

The output power of laser light 50 is required to be controlled within established standard safety levels for the protection of users, e.g., eyes and skin, and those who may be illuminated by such laser light, and the levels thereof can be different for pulsed laser light (instantaneous, peak values) and for continuous or average laser light, and may also be a function of the frequency of the pulses of laser light. For one example, Applicant understands that for a laser device to meet the requirements of FDA Class IIIa operation, when operated at or above 55 KHz, the maximum average laser power output must be limited by regulation to a level of 5 mW, however, to provide an additional margin of safety a lower power level, e.g., 3.3 mW, may be selected.

The FDA Class IIIa rules as Applicant understands them consider pulsed operation of a laser diode at a period of 18 usec or less to be treated as continuous wave (CW) operation and so the average laser output power and continuous wave laser output power are considered to be the same. Class IIIa is sometimes called Class 3a. A period of 18 usec or less generally corresponds to pulse rate or frequency of 55 KHz or higher. As a result, control and measurement of the average laser output power is sufficient for a device to qualify under Class IIIa if its average output power is less than 5 mW. Among the definitions set forth in ANSI Z136.1-2007, “American National Standard for Safe Use of Lasers” is the definition for “critical frequency.” That definition
is: “critical frequency. The pulse repetition frequency above which the laser output is considered continuous wave (CW). For example, for a short unintentional exposure (0.25 s to 10 s) to nanosecond (or longer) pulses, the critical frequency is 55 kHz for wavelengths between 0.40 and 1.05 μm, and 20 kHz for wavelengths between 1.05 and 1.40 μm.” AMERICAN NATIONAL STANDARD Z136.1-2007.

Although the frequency at which the pulses of laser light are produced affects the laser safety requirements, as a practical matter the inability of conventional laser drive circuits to control the current and duration of the pulses of laser drive current, and thus control the power level of the pulses of laser light, decreases as the frequency of the pulsing thereof increases, and the duration of the pulses becomes very short, e.g., microseconds.

An advantage of the semiconductor laser driver circuit 100 of the present arrangement is its ability control both the instantaneous and average power levels even though the pulse width of the laser drive current and thus the pulses of laser light are very small. At 55 KHz, the period of the drive pulse train is about 18 microseconds (usec) and the pulse width of each pulse thereof may be only 1-3 usec.

Because the instantaneous power level of the laser light produced by a semiconductor laser diode is proportional to the current flowing through the laser diode, whether continuous or pulsed, the present driver circuit monitors and controls the frequency, the pulse duration and the level of the current applied to the semiconductor laser, e.g., pulses of current, as described above, and also the average level of laser light produced thereby.

Semiconductor laser 50 includes in addition to the semiconductor laser diode LD, a photodiode PD that is illuminated by a portion of the light produced by laser diode LD so as to provide an accurately calibrated signal, e.g., a photodiode current, in known relationship to the actual optical laser output power. The current produced by photo diode PD flows through photodiode current sensor 48 which produces a feedback signal in known relationship to the average level of the laser light output power which is provided to controller 20 for producing control signals for power control 40 and high frequency switch 42 so that laser diode LD produces the desired power level of laser light, e.g., less than 5 mW.

The arrangement of photodiode PD and photodiode current sensor 48 sensing average photodiode current which is proportional to the actual laser diode LD output power also serves to provide a safety override in the unlikely event of a malfunction in the current controlling circuitry 40, 42, 44, 46. For example, should the malfunction cause the current applied to laser diode to not be limited to the desired pulse width duration or level in a way that the sample and hold circuit 46 sampling the laser diode LD current does not provide a feedback signal representing the actual laser diode current, current sensor 48 will provide an independent true average value feedback signal that controller 20 can utilize to limit the laser diode current and power output to remain within the desired limit for safety.

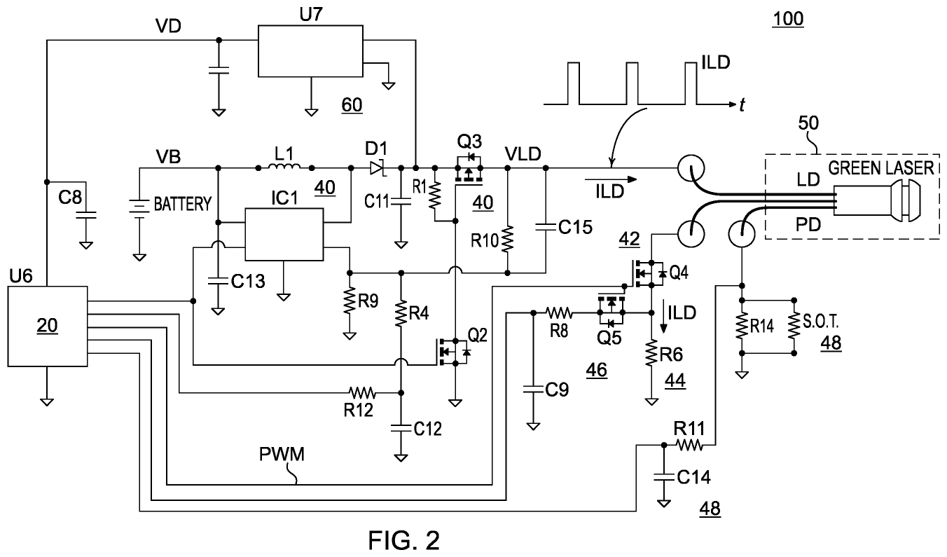

FIG. 2 is a schematic circuit diagram of an example embodiment of an electronic circuit 100 including an example embodiment of a driver circuit for a semiconductor laser. Therein, the item numbers corresponding to FIG. 1 are marked near the circuit elements relating to the corresponding function as described in relation to FIG. 1.

Power control 40 includes integrated circuit IC1 which contains a switching transistor between the L1-D1 connection and ground and is in circuit with inductor L1, diode D1 and capacitor C11 configured in a voltage boosting DC converter configuration for raising the voltage provided by battery B from its nominal value of about 3.2 VDC to a higher voltage VLD to be provided or applied to laser 50, e.g., typically about 5.3 V at room temperature (about 4.3-5.7 V at 110 mA, depending upon temperature), which corresponds to the desired level of current that is to flow through a typical laser diode LD. It is the current ILD flowing through laser diode LD that is controlled by controller 20 to be at the desired value, e.g., about 110 milliamperes (mA), to produce the desired laser light output power. Controller 20 receives feedback signals, e.g., laser diode current ILD, laser output power, and responds thereto to provide a control signal to IC1 via low pass filter provided by resistor R12 and capacitor C12 to establish the pulse width of the ON time of a transistor internal to IC1 that produces, e.g., by pulse width modulation (PWM), also known as duty cycle modulation, in combination with the rest of driver circuit 100, the desired current ILD. Power control 40 integrated circuit IC1 also receives feedback signals, e.g., voltage feedback via resistors R9 and R10 (and capacitor C15) for controlling output voltage VLD of power control 40 to produce the desired current ILD that flows in laser diode LD.

This circuitry adjusts the boosted output voltage VLD from power control 40 to produce the desired level of current ILD flowing in laser diode LD. Feedback through the lowpass filter R12, C12 offsets the fed back output voltage in order to adjust for the expected full range of voltage required to produce the desired current through laser diode LD, e.g., from less than 4.3 V to 7.5 V or more. Filter R12, C12 smooths the PWM signal from controller 20, U6 and is applied via ballast resistor R4 the value of which adjusts, e.g., increases or decreases, the effect of the smoothed PWM signal on the value of VLD produced by power control 40, the booster circuit IC1, L1, D1, C11.

Power control 40 also includes a switch transistor Q3 that is enabled by controller 20, U6 to be ON when current is to be applied to laser diode LD via high frequency switch 42. Controller 20, U6 provides a signal to IC1 to enable the boost DC converter of power control 40 to operate and that signal drives transistor Q2 to turn ON and to in turn power transistor Q3 to turn ON as well, thus applying the output from the boost DC converter to the high frequency switch 42. This arrangement with transistor Q3 helps to reduce the standby power drain when laser diode was not to be powered ON.

High-frequency switch 42 includes a switching transistor Q4, e.g., a field effect transistor (FET), in series with laser diode LD and current sensor 44, R6 by a pulse train generated by controller 20 from the values of the feedback signals coupled thereto from current sensor 44, R6 via sample and hold circuit 46. The pulse width modulated signal from controller 20 turns switching transistor Q4 ON and OFF at the PWM signal rate and timing, e.g., at the preferred 55 KHz or higher pulse rate frequency, thereby to apply pulses of voltage VLD to laser diode LD causing pulses of current ILD of the desired value and pulse width to flow through laser diode LD.

Semiconductor laser 50 includes laser diode LD and photo diode PD as described. Resistor R6 of current sensor 44 is in series with laser diode LD to sense the current ILD flowing therethrough and resistor R14 is in series with photodiode PD to sense the current generated thereby when laser light generated by laser diode LD impinges thereon, e.g., at the operating frequency and pulse duration of driver circuit 100. Transistor Q4 of high frequency switch 42 and transistor Q5, e.g., a field effect transistor (FET), of sample and hold circuit 46, being driven by the same PWM signal produced by controller 20, U6, are switched ON and OFF in synchronism with each other at the operating frequency of driver circuit 100, e.g., 55 KHz or higher, thereby synchronizing high frequency switch 42 and sample and hold circuit 46.

Sample and hold circuit 46 includes switching transistor Q5 which is connected to current sensing resistor R6 which is preferably of a low ohmic value to reduce power loss. Switching transistor Q5 switches ON in response to a pulse train generated by controller 20 in synchronism with Q4 thereby to periodically connect current sensing resistor R6 to resistor R8 and capacitor C9 thereby to provide a sample and hold circuit 46 that samples a signal representative of the current ILD through laser diode LD when that current flows and holds that signal value on capacitor C9 which is coupled to controller 20 as feedback of the laser diode current ILD for controlling the laser diode current ILD to be at the desired value, e.g., 110 mA, when periodically energized.

Controller 20 receives the ILD feedback signal from C9 and compares that to a reference value using the difference therebetween to either increase or decrease the width (time duration) of the PWM signal pulses that via R12 and R4 adjust the voltage booster 40 output voltage applied to laser diode LD via transistor Q4 of the high frequency switch 42 and sampled by transistors Q5 of sample and hold circuit 46. At the same time controller 20 also increases or decreases the value of the reference signal it applies to boost DC converter IC1 of power control 40 to adjust its output voltage VLD to the value needed for having laser diode LD conduct the desired level of pulsed current ILD. It is the magnitude of the laser diode current ILD pulses that are controlled by the above described feedback loop and the laser diode voltage VLD follows the demands for maintaining current pulse ILD at the value to which it is programmed to be controlled.

It is noted that the unique arrangement of high frequency switch 42 and sample and hold 46 enables the accurate sensing of relatively low current feedback signal voltages produced by current sensor 44. As a result, resistor R6 of current sensor 44 can have a relatively low ohmic value, e.g., a resistance between 1 and 10 Ohms and typically 1 Ohm, whereby relatively little power, e.g., about 2% or less in the described example, is dissipated in the current sensing resistor thereby increasing circuit efficiency and the like.

Photodiode PD of laser 50 is illuminated by laser light generated by laser diode LD whereby it generates a photo current that is proportional to the instantaneous output power level of laser diode LD, which photo current flows through current sensor 48. Current sensor 48 includes a sensing resistor R14 to generate an instantaneous current feedback signal that is averaged by a low pass filter such as that provided by resistor R11 and capacitor C14, and that is provided thereby as an average laser output power feedback signal to controller 20 to provide independent limiting of laser output power. This averaged feedback signal is compared with a reference level and is used by controller 20 to monitor and limit the average output power of laser diode LD, which level is set to maintain that average power to a level that is less than the maximum allowed safe level, e.g., 5 mW, and in this example 3.3 mW.

Because the calibration between the laser light power output of laser diode LD and the photodiode current produced by photodiode PD varies substantially from unit to unit of semiconductor laser 50, an adjustment for setting the safe power output level limit is provided. In parallel with photodiode sensing resistor R14 is provided a select-on-test (S.O.T.) resistor S.O.T. which is selected as part of the calibration of electronic circuit 100 in combination with the unit of laser 50 being driven thereby to provide a signal that is a known representation of the output power of laser diode LD that is utilized to provide feedback of the laser output power to controller 20 for the purpose of limiting that output power to a level that is no higher than the permitted safety limit, e.g., 5 mW for a Class IIIa laser device. Photodiode current sensor 48 comprises resistor R14 (and adjustment resistor SOT) and capacitor C14 which form a low-pass filter that averages the feedback signal output from photodiode current sensor 48.

Electronic circuit 100 has a predetermined controlled start up process that ensures that the output power of laser diode LD does not exceed the maximum safe value during start up as might occur without such process. During start up, controller 20 sets a predetermined voltage on capacitor C12 to start the output of power control 40, e.g., boost circuit of IC1 thereof, at less than the voltage that will cause laser diode LD to produce laser light at an excess average output power level. In addition, transistor Q4 of high frequency switch 42 is initially driven at a relatively low PWM duty cycle (relatively short pulse width) that will keep the laser diode LD average output power to remain below the safety limit at the target level of current ILD pulsing.

At the same time, transistor Q5 of sample and hold 46 is driven synchronously with transistor Q4, whereby the cumulative voltage on capacitor C9 as sampled by controller 20 accurately reflects the actual laser diode current ILD, and this process continues until the desired predetermined operating condition is reached, e.g., until the current through current sensing resistor R6 and the corresponding voltage of capacitor C9 has increased or decreased to the predetermined operating level. Throughout the start up process and subsequent operation, transistors Q4 and Q5 are driven at a frequency of 55 KHz or higher by controller 20, U6. Resistor R8 and capacitor C9 tend to reduce the effect of switching delays between Q4 and Q5 and so the voltage of capacitor C9 takes time to charge to the full voltage produced across current sensing resistor R6 by laser diode current ILD, however, the voltage of C9 after several cycles of current ILD pulses does reach a voltage representative of the voltage across R6 and thus the laser diode current ILD.

Electronic circuit 100 may include a voltage regulator 60, which may include an integrated circuit U7, to provide a bias voltage VD from which controller 20 and other portions of the circuit 100 receive a relatively fixed voltage from which to operate. The voltage regulator may be a simple conventional voltage regulator or may include a DC converter.

Unless otherwise specified, the transistors illustrated and described in the example embodiments of this Application are field effect transistors (FETs), however, other forms of semiconductor switching devices may be employed in the drive circuit arrangement described herein. Although example embodiment of the drive circuit arrangement described herein is in the environment of a drive circuit for a semiconductor laser, e.g., a green semiconductor laser, it is suitable for use to drive other types and kinds of loads.

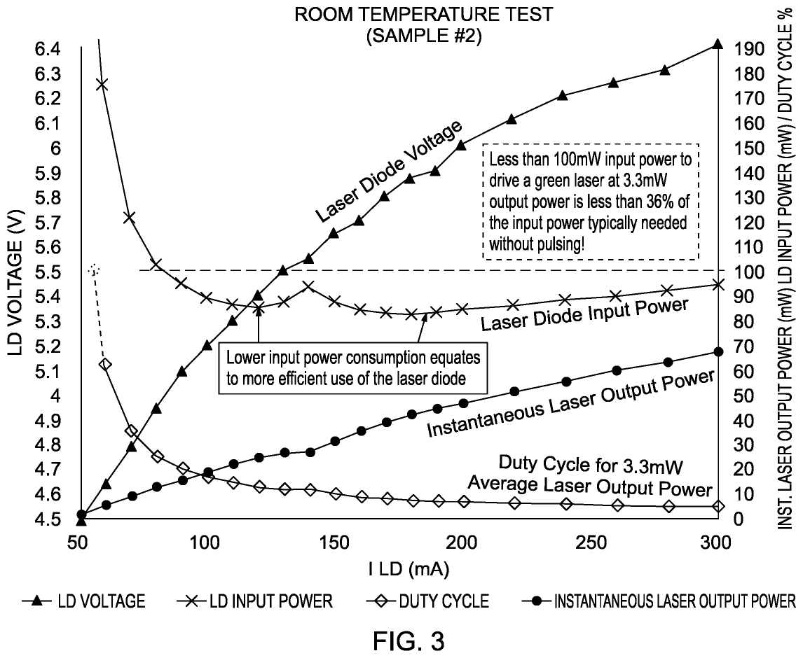

FIG. 3 is a graphical representation illustrating certain parameters relating to an example semiconductor laser. The horizontal axis is scaled in milliamperes (mA), e.g., 50-300 mA, of current ILD flowing through laser diode LD. The vertical axis at the left is marked for the voltage VLD in volts across laser diode LD represented as a function of current ILD (horizontal axis) by the rising graph line connecting data points indicated by triangular ▴ indicia. As one might expect of a diode, the voltage VLD across it increases as the current ILD through it increases. The left side vertical scale is for VLD between 4.5 V and 6.4 V (one example laser diode LD begins to lase, i.e. produce laser light, at a voltage of about 4.5 V and a threshold current ILD of about 25-35 mA).

The vertical axis at the right of FIG. 3 is a single scale from 0 to 190 for the three different parameters indicated along that axis. The horizontal dashed line is a reference line at 100 on the scale (also representing an operating condition of 100% duty cycle) to provide a visual reference to aid readability of the diagram. That reference line emphasizes the remarkable condition that the average laser diode input power is less than 100 mW for driving the example green laser diode at an average output power level of 3.3 mW which is only about 36% of the input power typically needed in continuous (CW) operation. The duty cycle of that operating condition is varied by the laser driver circuitry to produce a relatively low safe output power of, e.g., 3.3 mW average, which is below the permissible 5 mW average.

The other three graphical lines relative to the right hand vertical axis represent:
(1) The instantaneous laser output power (in mW) represented by the solid data line connecting data points thereof indicted by circular ● indicia;
(2) The laser diode LD average input power (in mW) represented by the solid data line connecting data points thereof indicated by an X indicia; and
(3) The duty cycle (ratio of ON time to total period of the pulse train) or DC (average) percentage of the pulsed current applied to laser diode LD represented by the solid line connecting data points thereof indicated by the diamond ⋄ indicia, that is needed to obtain 3.3 mW average laser output power.

As one might expect, as the voltage and current applied to the laser diode increase, i.e. the instantaneous input power to laser diode LD increases as the product thereof. It is noted that the relationship between input power and laser light output power is not linear because of the threshold current of the laser diode and because the efficiency of the conversion of electrical energy (input power) into optical energy (output power) varies as a function of the operating conditions of laser diode LD. At relatively lower voltages and currents, laser diode LD is relatively inefficient, which is where it is often operated in CW operation, and its efficiency increases as its voltage and current increase and then its efficiency decreases at relatively higher voltages and currents.

Operating the laser diode at higher current levels and low duty cycle enables the dramatic increase in efficiency provided by the drive circuit described herein. This is seen in the laser diode input data line (X data points) which reaches a minimum at intermediate levels of voltage and current.

With a constant average laser light output power, e.g., 3.3 mW, over the input current ILD range, the best laser diode efficiency is seen to be achieved in this example near laser drive currents ILD of 110-120 mA and at ILD≈180 mA, and average laser diode input power of about 83 mW (all approximate). When conventionally driven the example green laser diode requires about 280 mW input power to achieve the same laser diode output power that is achieved with about 83 mW in this example which includes a semiconductor laser drive circuit 100 as described herein—that is an improvement that reduces the input power by about 70% resulting in an operating runtime that is about 3.4 times longer.

Such dramatically longer runtime greatly extends battery lifetime and/or permits the use of a physically smaller or lower capacity battery to maintain the original runtime, and so is a very desirable advantage and of great advantage to the user. In devices, e.g., lights, where a single battery or power source supplies power for the laser diode and for another light source (or other load), the drive circuit described herein enable a more advantageous sharing of power between the various loads.

Continuing in the same example with the laser diode driver circuit 100 operating to apply pulses of current ILD through laser diode LD indicates a current pulse duty cycle of about 15% of the about 18 usec repetition period or an about 2.7 usec or shorter current pulse width, e.g., at an about 55 KHz pulse rate. Such extremely short pulse widths are too short to be provided or applied by, and to be sufficiently and efficiently controlled by, conventional laser diode drive circuits, but is achieved by the arrangement described herein.

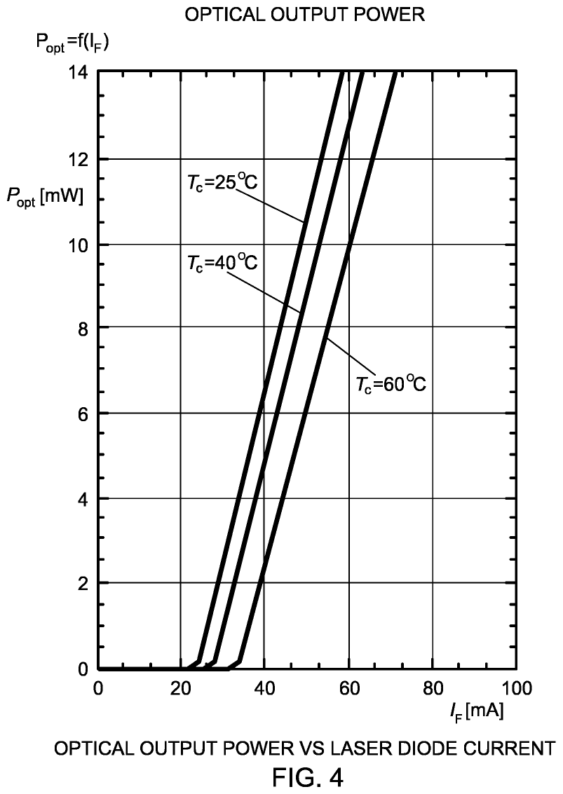

FIG. 4 is a graphical representation of the optical power output (Pₒₚₜ) versus the forward current (I_{F}) of an example semiconductor laser, as a function of temperature. Three example plots of Pₒₚₜ versus I_{F} are illustrated for continuous wave operation of the example green laser diode at temperatures of 25° C., 40° ° C. and 60° C. As temperature increases from 25° ° C. to 60° C., the current required to obtain a power output of 5 mW increases from about 35 mA to about 45 mA, for a power output of 3.3 mW, the current I_{F} increases from about 30 mA to about 42 mA, and the threshold current at the “knee” of the plot increases from about 25 mA to about 32 mA. Below the knee current, all the power applied to the laser diode produces heat and not laser light, and so the efficiency is zero. By pulsing the laser diode current to a much higher current level for a series of short time periods, e.g., relatively short duration pulses at a high repetition rate, e.g., 55 KHz or higher, the power dissipation below the knee becomes a much less significant portion of the total power applied during each pulse, and so there will be a significant improvement in the effective efficiency of the laser diode converting electrical energy into laser light energy. Controller 20 is or can be configured, as desired, to vary the laser diode current ILD correspondingly to the changes due to temperature so as to maintain a desired laser diode average output power.

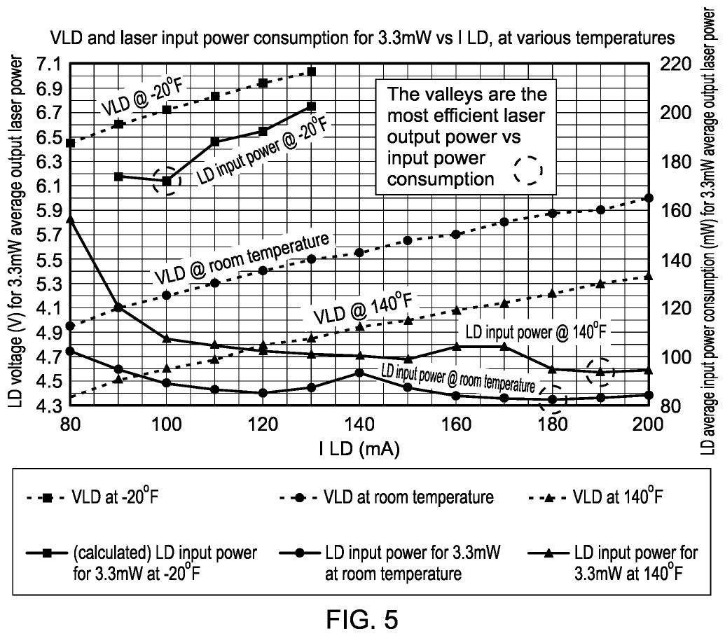

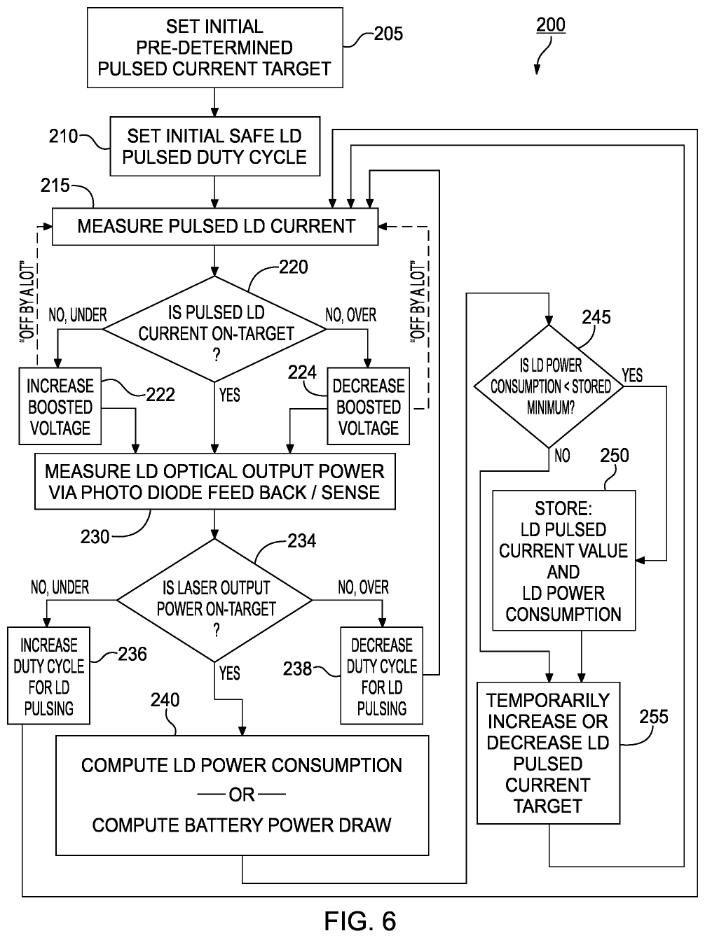

FIG. 5 is a graphical representation of the input power and forward voltage for an example semiconductor laser at various temperatures, and FIG. 6 is a schematic diagram of a process 200 for further increasing the operating efficiency of an example semiconductor laser in an example driver circuit as described herein. As thus far described, the semiconductor drive circuit enables a semiconductor laser to be operated at a desired pulsed current to provide a significant improvement in the efficiency of the semiconductor laser for a predetermined operation, e.g., a maximum average laser output power. The graphical representation of FIG. 5 illustrates characteristics, e.g., the voltage VLD and the input power, of the laser diode LD of semiconductor laser device 50 when operating to produce an average laser output power, e.g., of 3.3 milliwatts, at various operating temperatures, e.g., at −20° F. (Fahrenheit), at room temperature (about 70°), and at 140° F.

While the input voltage VLD to the semiconductor laser diode increases monotonically with increasing input current ILD, the input power exhibits a minimum value (has a “valley” indicated by dashed circles in the Figure) that is at a different level of input current ILD at different temperatures. Those minimums or valleys represent an operation condition whereat the semiconductor laser diode LD has its highest efficiency at that given temperature. As a result, it would be advantageous for the semiconductor laser drive circuit 100 to also control the operating point of the semiconductor laser diode LD to be at or near to its minimum input power level at the operating temperature present at any given time.

In the example of FIG. 5, electrical characteristics, e.g., VLD and LD average input power, of an example sample of a semiconductor laser device are illustrated for operating the device at three example temperatures, e.g., −20° F., room temperature (˜70° F.), and 140° F., and when producing 3.3 mW average laser output power. In the illustrated example, at room temperature the high efficiency operating point is at about ILD=180 milliamperes (mA) while at −20° F. it is at about 100 mA and at 140° F. it is at about 190 mA. It is understood that the specific operating conditions for each particular unit of a semiconductor laser device will vary from unit to unit and with varying electrical conditions and temperature.

Accordingly, it would be desirable for the described laser drive circuit to operate the semiconductor laser device at a high efficiency current ILD that is related to its characteristic over its operating temperature. In this operation, the desired ILD current may be different for different semiconductor laser devices and the high efficiency operating point may be different at different temperatures, and so controlling the operating point by controlling the laser device operating current ILD rather than relying on its operating temperature.

In the example embodiment of FIGS. 1 and 2, processor 20 or controller 20 controls the level and duty cycle of the laser current pulse ILD for controlling the operating conditions of the laser diode LD of semiconductor laser device 50, e.g., to produce a predetermined maximum average laser output power. A calculated level of laser diode current ILD nominally related with that output power operating condition may be referred to as a “target” laser current ILD. Processor 20 is configured to control the laser diode current ILD to be the “target” laser diode current ILD, e.g., by changing the magnitude of voltage VLD and/or the duty cycle of the pulse that is applied to laser diode LD relative to an initial “target” current ILD.

In addition, to accommodate the variations in the operating conditions of laser diode LD in use, processor 20 may be and preferably is configured to change the “target” laser diode current ILD, e.g., by increasing or decreasing the magnitude of voltage VLD and/or the duty cycle of the pulse that is applied to laser diode LD, from the initial “target” current ILD to obtain a larger or smaller “target” current that corresponds to the laser diode current ILD that is approximately at the high efficiency operating point of laser diode LD under the then present electrical and temperature conditions. Thereafter, processor 20 will continue to change the operating point of laser diode LD as the then present electrical and temperature conditions change, thereby to maintain laser diode LD operating approximately at a high efficiency operating point.

FIG. 6 illustrates an example process 200 for the foregoing operation. Process 200 commences with the setting 205 of the initial predetermined level, e.g., target level, of pulsed current ILD that is to be applied to the semiconductor laser diode LD to produce the desired average laser output power, e.g., 3.3 mW average, and with the setting 210 of the duty cycle to a predetermined safe initial level, e.g., 10%, of the pulsed laser current (duty cycle being the ratio of the on-time of the pulse to the time period between the start time of successive pulses of laser current). Having set 205, 210 those initial levels, the resulting pulsed laser diode current ILD is measured 215 and is compared 220 with the target level of the pulsed laser diode current ILD. When the target current is on target, i.e. is at the target or desired current level, then process proceeds to step 230 to measure average optical output power produced by semiconductor laser device 50

However, when the target pulsed current to laser diode LD is under the target level, then the laser diode current ILD is increased 222 by a predetermined amount, e.g., by increasing the output voltage VLD from power control 40 that determines the voltage of the pulses and the laser diode current ILD that they produce, and when the target current is over the target level, then the laser diode current ILD is decreased 224 by a predetermined amount, e.g., by decreasing the output voltage VLD from power control 40 and therefore the current level of the pulses. However, when the pulsed current ILD is significantly above (“off by a lot”) or significantly below (“off by a lot”), then process 200 returns from step 222 or from step 224 to again measure 215 and compare 220 the pulsed laser diode current ILD repeatedly until ILD is close to the target level, at which time process 200 proceeds to step 230 to measure average optical output power produced by semiconductor laser device 50.

Step 230 measures the average output power of the semiconductor laser diode LD using the value thereof provided by the photodiode PD current in semiconductor laser device 50 which is included therein and is calibrated to produce a current, e.g., a sensing current or a feedback current, that is proportional to the average output power from laser diode LD. This step begins an independent monitoring of the average laser output power to control the average laser output power, e.g., to keep that power within safety limits, in addition to the natural control of the average laser output power resulting from the controlling of the laser diode current ILD in steps 215 through 224.

Using the photodiode PD current to limit the average laser output power begins with comparing 234 the average laser diode output power using the feedback current measured by current sensor 48 from step 230 with the predetermined limit value therefor, e.g., the on-target value, e.g., 3.3 mW. When the average output power is the predetermined value, then process 200 proceeds to step 240 to compute the laser diode LD power consumption.

When the average output power of the laser diode LD is less than (under or below) the predetermined value, then the duty cycle for the applying pulsed current ILD to the laser diode LD is increased 236 and process 200 returns to step 215 to again measure the level of the pulsed laser diode current ILD. When the average output power is greater than (over or above) the predetermined value, then the duty cycle for the applying pulsed current ILD to the laser diode LD is decreased 238 and process 200 returns to step 215 to again measure the level of the pulsed laser diode current ILD. Steps 234-236-238 with preceding steps 215 to 230 repeat as needed to maintain the average laser diode output power at the predetermined average power level, e.g., the 3.3 mW safety limit, or less. When the foregoing steps 215-234 cause the average laser diode output power to be at the target level thereof, i.e. the output power is on target (240 Yes), and process 200 proceeds to step 240.

Step 240 includes computing 240 the power consumption of laser diode LD and/or computing 240 the power draw from the battery, and may include one or more of the following example methods: The laser diode LD power level may be computed/calculated 240 by multiplying the value of the duty cycle of the pulsed laser current ILD times the value of the laser diode boosted voltage VLD times the value of the laser diode pulsed current ILD. Alternatively, the battery power draw may be computed/calculated 240 by computing/calculating the value of the power being withdrawn from the power source, e.g., battery, and may include, e.g., multiplying the voltage VB measured at the battery terminals times the measured or computed value of the current flowing therefrom, e.g., its current draw. Both of these methods for step 140 can produce an instantaneous value, or may also produce a series of values that can be averaged, or that can be integrated to determine the cumulative average energy produced by the semiconductor laser diode LD and/or the cumulative energy withdrawn from the power source which may be used for managing the operating conditions for the semiconductor laser device and/or the light or other device including such laser device.

The laser diode LD power consumption from step 240—Yes is compared 245 with a predetermined minimum value thereof. When the laser diode LD power consumption is less than (245—Yes) the predetermined minimum value thereof, e.g., a value stored in memory of processor 20 or controller 20, then the present value of the pulsed laser diode current ILD and the present value of the laser diode LD power consumption are stored 250, e.g., in memory of processor 20, and process 200 proceeds to step 255 to adjust the level of the pulsed laser diode current ILD. When the laser diode LD power consumption is not less than (245—No) the predetermined minimum value thereof, (i.e. is greater than the predetermined minimum value thereof), then process 200 proceeds directly to step 255.

In a typical instance, step 255 serves to increase 255 the target value of the pulsed laser diode current ILD when the laser diode LD power consumption is less than the stored minimum value and to decrease 255 the target value of the pulsed laser diode current ILD when the laser diode LD power consumption is not less than the stored minimum value. However, there are or may be certain areas of the characteristics of the semiconductor laser diode LD wherein the preceding sentence is not the case, e.g., the area in FIG. 3 for ILD in the range approximately between 100 mA to 130 mA, in which case the change to the target value for ILD by the logic of step 255 may be opposite to that immediately above.

The logic of step 255 may be configured for the processor to determine whether to increase or to decrease the current ILD from the trend of its previous actions to increase or decrease the current ILD. The logic of step 255 may be configured alternatively and/or additionally to make adjustments to the level of pulsed laser diode current ILD in fixed increments and/or may be configured to make adjustments to the level of pulsed laser diode current ILD by calculating larger or smaller increments as a function of the magnitude of the difference between the stored minimum power level and the measured/computed power level.

Step 255 increases the laser diode pulsed current if increasing it has been reducing the computed power computed in step 240 or decreases the laser diode pulsed current if increasing it now increases the computed power computed in step 240, thereby to cause process to increase and decrease the output voltage 222, 224 and/or the pulsed current duration 236, 238 to tend to minimize the laser diode power consumption or the battery power drawer, as the case may be, thereby changing the operating conditions of laser diode LD to be at a high efficiency condition. In like manner, step 255 decreases the pulsed current ILD if decreasing ILD has been reducing the power computed in step 240 or increases the current ILD if decreasing ILD has been increasing the power computed in step 240.

Operating the laser diode LD at a high efficiency condition tends to minimize the power that is needed from the battery or other power source while maintaining the desired predetermined level of average laser diode output power, and so might be considered to be an “optimum” or a “near optimum” operating condition, if reducing the power consumed by the laser diode and/or drawn from the power source, e.g., battery, which tends to extend the run time of the light or other load.

Process 200 then returns to step 215 to again measure the pulsed laser diode current ILD and repeat process steps 215 to 255 for maintaining the operating conditions of laser diode LD within the predetermined values for pulsed laser diode current ILD and average laser diode output power while semiconductor drive circuit 100 and light 10 are operating, e.g., turned ON. In this manner the operation of semiconductor laser device 50 and of laser diode LD therein can be maintained within desired ranges and limits, e.g., for safe operation and human safety.

It is noted that the added functionality provided by process 200 may be employed at all times the semiconductor laser device of a light or other device is operating or only at certain operating times, as may be thought to be desirable. For example, one might decide to employ the functionality of process 200 only when the power source, e.g., battery, of a light 10 has become discharged by more than a predetermined amount, e.g., as may be determined from the terminal voltage of the power source or by accumulating the current or power drawn therefrom, thereby to further extend the operating time of the light or other device employing circuit 100. The latter option can help to limit the maximum current drawn from the power source, e.g., battery, as its terminal voltage decreases as it is discharged, which may protect the battery and/or extend the runtime of the light or device.

Consider a particular operating example set forth in this paragraph and the next five paragraphs of a typical operating scenario of the foregoing process 200, keeping in mind that the conditions are examples and will change with the particular characteristics of each unit of the semiconductor laser driver circuit 100, of the values and tolerances of the electronic components therein, of semiconductor laser device 50, of the source of electrical power, and of temperature and other environmental factors. Suppose the current ILD of the semiconductor laser LD is running at the initial value of 110 mA with the corresponding laser diode LD power consumption at 86 mW. Then the operating parameters “86 mW” at “110 mA” are stored in memory as the presumed “minimum” power consumption because that is the only data point thus far.

Processor 20 may “test the waters,” i.e. to determine what the result is when the laser diode target current ILD is reduced to 100 mA. Making a reduction may be chosen first because of, e.g., a preference to not operate as close to the rated maximum current capability of the semiconductor laser LD if it is not “necessary” to do so. When the current ILD is set to 100 mA, the power consumption of laser diode LD is found to increase to about 89 mW, indicating that the chosen direction of changing the current level was in the wrong direction, however, the operating parameters of laser diode LD are within safe limits In response, processor 20 step 255 returns to ILD=110 mA and the power consumption returns to about 86 mW, i.e. “86 mW” at “110 mA” is still the desired minimum power consumption, i.e. higher efficiency, condition.

Because the previous reduction of laser diode current ILD to 100 mA caused the power consumption to increase, processor 20 may again “tests the waters” to determine what the result will be if the ILD target is increased to 120 mA. Then, operating at ILD=120 mA, laser diode LD power consumption decreases to about 85 mW which determines a new minimum power operating point: “85 mW” at “120 mA” which is stored in memory as the new minimum power, i.e. higher efficiency, condition.

Next processor 20 step 255 again “tests the waters” to determine what the result will be when the target current value for ILD is further increased to 130 mA. At that new operating condition, the power consumption is about 87 mW determining that the current ILD has been increased “too far.” Consequently, processor 20 step 255 returns to ILD=120 mA, the previously determined “optimized” operating point; however, suppose e.g., that the power consumption at ILD=120 mA is now about 86 mW due to, e.g., a temperature change. Thus “86 mW” at “120 mA” is now stored in memory as the minimum power consumption operating point.

Some predetermined time later, for example, processor 20 step 255 may attempt to “test the waters” again by doing a step down, i.e. reduction, in the target level of the pulse current ILD. If that reduction in ILD results in a reduced (or the same) power consumption, that changed operating condition would become the new “optimum” operating point and the processor would then attempt another step down in ILD to determine whether a lower power consumption will or will not occur.

Otherwise, processor 20 would return to the previously determined “optimum” level of current ILD and subsequently attempt a step up, i.e. increase, in target current ILD. If that ILD current level causes power consumption to be reduced (or to remain the same), that operating condition would become the new “optimum” operating point and the processor 20 step 255 would attempt another step up, i.e. increase, in current ILD. If that most recent step up in current ILD were to cause an increase in power consumption, processor 20 would return to the previously determined “optimum” level of current ILD for some predetermined time until it again “ventures out” to again “test the waters.” Thus ends the foregoing six paragraph example.

In a typical embodiment, in some instances in a preferred embodiment, the described arrangement operates efficiently with a semiconductor laser diode LD that produces green laser light, e.g., light at about 510-530 nm, and more generally light in the visible light range of about 400-700 nm. The present drive circuit is also advantageous for driving other devices that exhibit a threshold input level and/or higher efficiency at higher current and shorter pulse widths, e.g., a blue laser diode is but one example of such device. It is noted that drive circuit efficiencies that are about 2-3 times greater than that of conventional laser diode drive circuits has been realized with the described drive circuit 100.

A driver circuit for supplying pulses of electrical power to a load may comprise: a power control receiving input power and converting that input power to an output voltage; a high frequency switch configured to provide or apply short duration pulses of the output voltage to a load causing a pulsed load current of like duration to flow therethrough; a current sensor through which the pulsed load current flows for generating a signal representative of the pulsed load current; a sample and hold circuit configured to sample the signal representative of the pulsed load current in synchronism with the high frequency switch and to hold the sampled signal value; and a controller receiving the sampled signal value and responsive thereto and to a reference value, and configured to apply control signals to the power control to produce the desired output voltage, and to the high frequency switch and the sample and hold circuit to control the pulsed load current to a predetermined value. The repetition rate of the pulsed load current is at least 55 KHz and the short duration thereof is less than 9 microseconds. The load may include: a semiconductor laser diode; or a green semiconductor laser diode; or a blue semiconductor laser diode; or a light emitting diode. The driver circuit wherein the controller: compares a measured value of the pulsed load current to a target value thereof, and increases the output voltage and/or the duration of the pulsed load current pulses when the measured value of the pulsed load current is less than the target value thereof and decreases the output voltage and/or the duration of the pulsed load current pulses when the measured value of the pulsed load current is greater than the target value thereof. The driver circuit wherein the controller: compares a measured value of the output of the load to a target value thereof, and increases the duration of the pulsed load current pulses when the measured value of the output of the load is less than the target value thereof and decreases the duration of the pulsed load current pulses when the measured or computed value of the output of the load is greater than the target value thereof. The driver circuit wherein the controller: determines a power consumption by computing power consumption of the load or computing power drawn from a power source; stores the power consumption when the most recently determined value thereof is less than a previously stored value thereof; and changes the duration of the pulsed load current pulses in a direction to further decrease the determined power consumption.

A driver circuit for supplying pulses of electrical power to a light producing semiconductor device may comprise: a power control including a DC converter receiving input power and converting that input power to an output voltage; a high frequency switch transistor configured to provide or apply short duration pulses of the output voltage to a light producing semiconductor device causing a pulsed load current of like duration to flow therethrough; a current sensing resistor through which the pulsed load current flows for generating a signal representative of the pulsed load current; a sample and hold circuit including a switch transistor configured to sample the signal representative of the pulsed load current in synchronism with the high frequency switch transistor and to hold the sampled signal value; and a controller receiving the sampled signal value and responsive thereto and to a reference value, configured to apply a control signal to the power control to produce the desired output voltage, and to apply a pulse width modulated drive signal to the high frequency switch transistor and to the sample and hold circuit switch transistor to control the pulsed load current to a predetermined value. The repetition rate of the pulsed current in the light producing semiconductor device is at least 55 KHz and the short duration thereof is less than 9 microseconds. The light producing semiconductor device may include: a semiconductor laser diode; or a green semiconductor laser diode; or a blue semiconductor laser diode; or a light emitting diode. The driver circuit wherein the controller: compares a measured value of the pulsed light producing semiconductor device current to a target value thereof, and increases the output voltage and/or the duration of the pulsed light producing semiconductor device current pulses when the measured value of the pulsed light producing semiconductor device current is less than the target value thereof and decreases the output voltage and/or the duration of the pulsed light producing semiconductor device current pulses when the measured value of the pulsed light producing semiconductor device current is greater than the target value thereof. The driver circuit wherein the controller: compares a measured value of the output of the light producing semiconductor device to a target value thereof, and increases the duration of the pulsed light producing semiconductor device current pulses when the measured value of the output of the light producing semiconductor device is less than the target value thereof and decreases the duration of the pulsed light producing semiconductor device current pulses when the measured or computed value of the output of the light producing semiconductor device is greater than the target value thereof. The driver circuit wherein the controller: determines a power consumption by computing power consumption of the light producing semiconductor device or computing power drawn from a power source; stores the power consumption when the most recently determined value thereof is less than a previously stored value thereof; and changes the duration of the pulsed light producing semiconductor device current pulses in a direction to further decrease the determined power consumption.

A method for supplying pulses of electrical power to a load may comprise: converting an input power to an output voltage; providing or applying high frequency short duration pulses of the output voltage to a load causing a pulsed load current of like duration to flow therethrough; sensing the pulsed load current flow for generating a signal representative of the pulsed load current; sampling the signal representative of the pulsed load current in synchronism with the high frequency short duration pulses and holding the sampled signal value; and receiving the sampled signal value and a reference value, and applying control signals responsive to the sampled signal value and to the reference value to produce a desired output voltage and to control the high frequency short duration pulses and the sampling and holding to control the pulses of electrical power to a predetermined value. The method wherein the high frequency repetition rate of the pulsed load current is at least 55 KHz and the short duration thereof is less than 9 microseconds. The method may further comprise: establishing a target value as the reference value for the pulsed load current; measuring the value of the pulsed load current; comparing the measured value of the pulsed load current to the target value thereof, increasing the output voltage and/or the duration of the pulsed load current pulses when the measured value of the pulsed load current is less than the target value thereof and decreasing the output voltage and/or the duration of the pulsed load current pulses when the measured value of the pulsed load current is greater than the target value thereof; and repeating the preceding steps. The method may further comprise: establishing a target value for an output of the load; measuring the value of the output of the load; comparing the measured value of the output of the load to the target value thereof, increasing the duration of the pulsed load current pulses when the measured value of the output of the load is less than the target value thereof and decreasing the duration of the pulsed load current pulses when the measured or computed value of the output of the load is greater than the target value thereof; and repeating the preceding steps. The method may further comprise: determining a power consumption by computing power consumption of the load or computing power drawn from a power source; storing the power consumption when the most recently determined value thereof is less than a previously stored value thereof; and changing the duration of the pulsed load current pulses in a direction to further decrease the determined power consumption. The method wherein the load includes: a semiconductor laser diode; or a green semiconductor laser diode; or a blue semiconductor laser diode; or a light emitting diode.

A method for supplying pulses of electrical power to a laser diode may comprise: converting an input power to an output voltage; providing or applying high frequency short duration pulses of the output voltage to a laser diode causing a pulsed laser diode current of like duration to flow therethrough; sensing the pulsed laser diode current flow for generating a signal representative of the pulsed laser diode current; sampling the signal representative of the pulsed laser diode current in synchronism with the high frequency short duration pulses and holding the sampled signal value; and receiving the sampled signal value and a reference value, and applying control signals responsive to the sampled signal value and to the reference value to produce a desired output voltage and to control the high frequency short duration pulses and the sampling and holding to control the pulses of electrical power to a predetermined value. The method wherein the high frequency repetition rate of the pulsed laser diode current is at least 55 KHz and the short duration thereof is less than 9 microseconds. The method may further comprise: (a) establishing a target value as the reference value for the pulsed laser diode current; (b) measuring the value of the pulsed laser diode current; comparing the measured value of the pulsed laser diode current to the target value thereof, increasing the output voltage and/or the duration of the pulsed laser diode current pulses when the measured value of the pulsed laser diode current is less than the target value thereof and decreasing the output voltage and/or the duration of the pulsed laser diode current pulses when the measured value of the pulsed laser diode current is greater than the target value thereof; and repeating the preceding steps. The method may further comprise: establishing a target value for an output of the laser diode; measuring the value of the output of the laser diode; comparing the measured value of the output of the laser diode to the target value thereof, increasing the duration of the pulsed laser diode current pulses when the measured value of the output of the laser diode is less than the target value thereof and decreasing the duration of the pulsed laser diode current pulses when the measured or computed value of the output of the laser diode is greater than the target value thereof; and repeating the foregoing steps. The method may further comprise: determining a power consumption by computing power consumption of the laser diode or computing power drawn from a power source; storing the power consumption when the most recently determined value thereof is less than a previously stored value thereof; and changing the duration of the pulsed laser diode current pulses in a direction to further decrease the determined power consumption. The laser diode may include: a semiconductor laser diode; or a green semiconductor laser diode; or a blue semiconductor laser diode; or a light emitting diode.

As used herein, the terms “about,” “approximate” and/or “approximately” mean that dimensions, sizes, formulations, parameters, shapes and other quantities and characteristics are not and need not be exact, but may be approximate and/or larger or smaller, as desired, reflecting tolerances, conversion factors, rounding off, measurement error and the like, judgment, and other factors known to those of ordinary skill in the art. In general, a dimension, size, formulation, parameter, shape or other quantity or characteristic is “about” or “approximate” or “substantial” or “substantially” whether or not expressly stated to be such. It is noted that embodiments of very different sizes, shapes and dimensions may employ the described arrangements.

As used herein, the term “and/or” encompasses both the conjunctive and the disjunctive cases, so that a phrase in the form “A and/or B” encompasses “A” or “B” or “A and B.” Likewise, a phrase in the form “A, B and/or C” or a phrase in the form “A and/or B and/or C” includes “A,” “B,” “C,” “A and B,” “A and C,” “B and C,” and “A and B and C.” In addition, the term “at least one of” one or more elements is intended to include one of any one of the elements, more than one of any of the elements, and two or more of the elements up to and including all of the elements, and so, e.g., phrases in the form “at least one of A, B and C” include “A,” “B,” “C,” “A and B,” “A and C,” “B and C,” and “A and B and C.”

As used herein in relation to the power applied to the semiconductor laser diode, the term “short” means the duration of the pulse of electrical power applied to the semiconductor laser diode is equal to or is less than that necessary for the laser diode to be operating in FDA Class IIIa which permits a maximum average output power of 5 milliwatts (mW) when the period of the pulse train is 18 usec or less, e.g., a frequency of 55 KHz or higher. See, ANSI Z136.1-2007, “American National Standard for Safe Use of Lasers.”

As used herein, the term “predetermined” means determined in advance or beforehand with respect to whatever the term pertains to. The term may be used with respect to a physical object or thing and/or with respect to an intangible thing, e.g., a signal or data, and the like. Examples thereof may include a fixed value, position, condition and/or limit, however, predetermined is not limited to a fixed value, position, condition and/or limit. A predetermined value, position, condition and/or limit may change or otherwise vary over time, over a sequence and/or over a randomized series of values, positions, conditions and/or limits.

As used herein, the terms “substantial” and “substantially” mean that the thing referred to as being “substantial” or “substantially” is sufficiently similar in form and/or function as to usable in the invention in a manner that is encompassed or suggested by the description and/or claims herein, and/or an equivalent thereof. The terms “substantial” and “substantially” can include and/or can be in addition to the meaning of the terms “about,” “approximate” and/or “approximately” herein.

As used herein, the terms “connected” and “coupled” as well as variations thereof may or may not be intended to be exact synonyms, but may also encompass some similar things and some different things, and those terms are used interchangeably herein. While the term “connected” as indicated by its context may be used generally to refer to elements that have a direct electrical and/or physical contact to each other, whereas the term “coupled” as indicated by its context may be used generally to refer to elements that have an indirect electrical and/or indirect physical contact with each other, e.g., via one or more intermediate elements, so as to cooperate and/or interact with each other, and may include elements in direct contact as well.

The term “battery” may be used herein to refer generally to a source of electrical power as well as to an electro-chemical device comprising one or more electro-chemical cells and/or fuel cells, and so a battery may include a single cell or plural cells, whether as individual units or as a packaged unit. A battery is one example of a type of an electrical power source suitable for a portable or other device. Such devices could employ power sources including, but not limited to, fuel cells, super capacitors, solar cells, and the like, as well as an electro-chemical battery. Any of the foregoing may be intended for a single use or for being rechargeable or for both, and/or plural ones thereof may be combined into a battery pack or battery assembly or other such assembly or pack, and any, some or all thereof may be referred to herein under the general term battery.

Various embodiments of a battery may have one or more battery cells, e.g., one, two, three, four, or five or more battery cells, as may be deemed suitable for any particular device. A battery may employ various types and kinds of battery chemistry types, e.g., a carbon-zinc, alkaline, lead acid, nickel-cadmium (Ni—Cd), nickel-metal-hydride (NiMH) or lithium-ion (Li-Ion) or lithium-ion-phosphate battery type, of a suitable number of cells and cell capacity for providing a desired operating time and/or lifetime for a particular device, and may be intended for a single use or for being rechargeable or for both. Examples may include three cell Ni—Cd or NiMH battery typically producing about 3.6 volts, a Li-Ion battery typically producing about 3.5-3.7 volts, it being noted that the voltages produced thereby will be higher when approaching full charge and will be lower in discharge, particularly when providing higher current and when reaching a low level of charge, e.g., becoming discharged.

Power control 40 and/or power regulator 30 and/or regulator 60 may be, e.g., DC converters. The term DC converter is used herein to refer to any electronic circuit that receives at an input electrical power at one voltage and current level and provides at an output DC electrical power at a different voltage and/or current level. Examples may include a DC-DC converter, an AC-DC converter, a boost converter, a buck converter, a buck-boost converter, a single-ended primary-inductor converter (SEPIC), a linear regulator, a series regulating element, a current level regulator, and the like. The input and output thereof may be DC coupled and/or AC coupled, e.g., as by a transformer and/or capacitor. A DC converter may or may not include circuitry for regulating a voltage and/or a current level, e.g., at an output thereof, and may have one or more outputs providing electrical power at different voltage and/or current levels and/or in different forms, e.g., AC or DC.

Further, what is stated as being “optimum” or “deemed optimum” may or may not be a true optimum condition, but may be a condition deemed to be desirable or subjectively “optimum” by virtue of its being selected in accordance with the decision rules and/or criteria defined by the designer and/or applicable controlling function, e.g., the processor 20 or controller 20, and/or criteria of or relating to process 200.

While the present invention has been described in terms of the foregoing example embodiments, variations within the scope and spirit of the present invention as defined by the claims following will be apparent to those skilled in the art. For example, driver circuit 100 may be employed to drive other devices and loads wherein pulses of power are to be applied thereto at a relatively high frequency, e.g., a high pulse repetition rate. Examples include a semiconductor laser diode; or a green semiconductor laser diode; or a blue semiconductor laser diode; or a light emitting diode.

While the frequency at which laser diode drive circuit 100 operates has been described as being, at least typically, 55 KHz, that operating frequency may be higher and/or may vary over a range of frequencies, preferably of 55 KHz or greater. Both the pulse width of the PWM current ILD applied to laser diode LD and the frequency or repetition rate thereof may vary within predetermined ranges, so long as the frequency is 55 KHZ or greater. The repetition rate of the pulsed load current ILD is at least 55 KHz and the duty cycle of the PWM drive signal is relatively short at about 50% or less, e.g., typically less than about 40%, and so the short duration or pulse width thereof is less than about 9 microseconds, e.g., 7.2 μsec.

While the preferred current flowing through laser diode LD in the example embodiment described is, e.g., 110-120 mA at room temperature, that current level may be different for different laser diodes and at different temperatures.

Each of the U.S. Provisional applications, U.S. patent applications, and/or U.S. patents, identified herein is hereby incorporated herein by reference in its entirety, for any purpose and for all purposes irrespective of how it may be referred to or described herein.

Finally, numerical values stated are typical or example values, are not limiting values, and do not preclude substantially larger and/or substantially smaller values. Values in any given embodiment may be substantially larger and/or may be substantially smaller than the example or typical values stated.

What is claimed is:

1. A driver circuit for supplying pulses of electrical power to a load comprising:
a power control receiving input power and converting that input power to an output voltage;
a high frequency switch configured to provide short duration pulses of the output voltage to a load causing a pulsed load current of like duration to flow therethrough;
a current sensor through which the pulsed load current flows for generating a signal representative of the pulsed load current;
a sample and hold circuit configured to sample the signal representative of the pulsed load current in synchronism with the high frequency switch and to hold the sampled signal value; and
a controller receiving the sampled signal value and responsive thereto and to a reference value, and configured to apply control signals to the power control to produce the desired output voltage, and to the high frequency switch and the sample and hold circuit to control the pulsed load current to a predetermined value.

2. The driver circuit of claim 1 wherein the repetition rate of the pulsed load current is at least 55 KHz and the short duration thereof is less than 9 microseconds.

3. The driver circuit of claim 1 wherein the load includes:
a semiconductor laser diode; or
a green semiconductor laser diode; or
a blue semiconductor laser diode; or
a light emitting diode.

4. The driver circuit of claim 1 wherein the controller:
compares a measured value of the pulsed load current to a target value thereof, and
increases the output voltage and/or the duration of the pulsed load current pulses when the measured value of the pulsed load current is less than the target value thereof and decreases the output voltage and/or the duration of the pulsed load current pulses when the measured value of the pulsed load current is greater than the target value thereof.

5. The driver circuit of claim 4 wherein the controller:
compares a measured value of the output of the load to a target value thereof, and
increases the duration of the pulsed load current pulses when the measured value of the output of the load is less than the target value thereof and decreases the duration of the pulsed load current pulses when the measured or computed value of the output of the load is greater than the target value thereof.

6. The driver circuit of claim 5 wherein the controller:
determines a power consumption by computing power consumption of the load or computing power drawn from a power source;
stores the power consumption when the most recently determined value thereof is less than a previously stored value thereof; and
changes the duration of the pulsed load current pulses in a direction to further decrease the determined power consumption.

7. A method for supplying pulses of electrical power to a load comprising:
converting an input power to an output voltage;
providing high frequency short duration pulses of the output voltage to a load causing a pulsed load current of like duration to flow therethrough;
sensing the pulsed load current flow for generating a signal representative of the pulsed load current;
sampling the signal representative of the pulsed load current in synchronism with the high frequency short duration pulses and holding the sampled signal value; and
receiving the sampled signal value and a reference value, and applying control signals responsive to the sampled signal value and to the reference value to produce a desired output voltage and to control the high frequency short duration pulses and the sampling and holding to control the pulses of electrical power to a predetermined value.

8. The method of claim 7 wherein the high frequency repetition rate of the pulsed load current is at least 55 KHz and the short duration thereof is less than 9 microseconds.

9. The method of claim 7 further comprising:
(a) establishing a target value as the reference value for the pulsed load current;
(b) measuring the value of the pulsed load current;
(c) comparing the measured value of the pulsed load current to the target value thereof,
(d) increasing the output voltage and/or the duration of the pulsed load current pulses when the measured value of the pulsed load current is less than the target value thereof and decreasing the output voltage and/or the duration of the pulsed load current pulses when the measured value of the pulsed load current is greater than the target value thereof; and
(e) repeating steps (b) through (d) of this claim.

10. The method of claim 9 further comprising:
(a) establishing a target value for an output of the load;
(b) measuring the value of the output of the load;
(c) comparing the measured value of the output of the load to the target value thereof,
(d) increasing the duration of the pulsed load current pulses when the measured value of the output of the load is less than the target value thereof and decreasing the duration of the pulsed load current pulses when the measured or computed value of the output of the load is greater than the target value thereof; and
(e) repeating steps (b) through (d) of this claim.

11. The method of claim 10 further comprising:
determining a power consumption by computing power consumption of the load or computing power drawn from a power source;
storing the power consumption when the most recently determined value thereof is less than a previously stored value thereof; and
changing the duration of the pulsed load current pulses in a direction to further decrease the determined power consumption.

12. The method of claim 7 wherein the load includes:
a semiconductor laser diode; or
a green semiconductor laser diode; or
a blue semiconductor laser diode; or
a light emitting diode.

13. A driver circuit for supplying pulses of electrical power to a light producing semiconductor device comprising:
a power control including a DC converter receiving input power and converting that input power to an output voltage;
a high frequency switch transistor configured to provide short duration pulses of the output voltage to a light producing semiconductor device causing a pulsed light producing semiconductor device current of like duration to flow therethrough;
a current sensing resistor through which the pulsed light producing semiconductor device current flows for generating a signal representative of the pulsed light producing semiconductor device current;
a sample and hold circuit including a switch transistor configured to sample the signal representative of the pulsed light producing semiconductor device current in synchronism with the high frequency switch transistor and to hold the sampled signal value; and
a controller receiving the sampled signal value and responsive thereto and to a reference value, configured to apply a control signal to the power control to produce the desired output voltage, and to apply a pulse width modulated drive signal to the high frequency switch transistor and to the sample and hold circuit switch transistor to control the pulsed light producing semiconductor device current to a predetermined value.

14. The driver circuit of claim 13 wherein the repetition rate of the pulsed current in the light producing semiconductor device is at least 55 KHz and the short duration thereof is less than 9 microseconds.

15. The driver circuit of claim 13 wherein the light producing semiconductor device includes:
a semiconductor laser diode; or
a green semiconductor laser diode; or
a blue semiconductor laser diode; or
a light emitting diode.

16. The driver circuit of claim 13 wherein the controller:
compares a measured value of the pulsed light producing semiconductor device current to a target value thereof, and
increases the output voltage and/or the duration of the pulsed light producing semiconductor device current pulses when the measured value of the pulsed light producing semiconductor device current is less than the target value thereof and decreases the output voltage and/or the duration of the pulsed light producing semiconductor device current pulses when the measured value of the pulsed light producing semiconductor device current is greater than the target value thereof.

17. The driver circuit of claim 16 wherein the controller:
compares a measured value of the output of the light producing semiconductor device to a target value thereof, and
increases the duration of the pulsed light producing semiconductor device current pulses when the measured value of the output of the light producing semiconductor device is less than the target value thereof and decreases the duration of the pulsed light producing semiconductor device current pulses when the measured or computed value of the output of the light producing semiconductor device is greater than the target value thereof.

18. The driver circuit of claim 17 wherein the controller:
determines a power consumption by computing power consumption of the light producing semiconductor device or computing power drawn from a power source;
stores the power consumption when the most recently determined value thereof is less than a previously stored value thereof; and
changes the duration of the pulsed light producing semiconductor device current pulses in a direction to further decrease the determined power consumption.

19. A method for supplying pulses of electrical power to a laser diode comprising:
converting an input power to an output voltage;
providing high frequency short duration pulses of the output voltage to a laser diode causing a pulsed laser diode current of like duration to flow therethrough;
sensing the pulsed laser diode current flow for generating a signal representative of the pulsed laser diode current;
sampling the signal representative of the pulsed laser diode current in synchronism with the high frequency short duration pulses and holding the sampled signal value; and
receiving the sampled signal value and a reference value, and applying control signals responsive to the sampled signal value and to the reference value to produce a desired output voltage and to control the high frequency short duration pulses and the sampling and holding to control the pulses of electrical power to a predetermined value.

20. The method of claim 19 wherein the high frequency repetition rate of the pulsed laser diode current is at least 55 KHz and the short duration thereof is less than 9 microseconds.

21. The method of claim 19 further comprising:
(a) establishing a target value as the reference value for the pulsed laser diode current;
(b) measuring the value of the pulsed laser diode current;
(c) comparing the measured value of the pulsed laser diode current to the target value thereof,
(d) increasing the output voltage and/or the duration of the pulsed laser diode current pulses when the measured value of the pulsed laser diode current is less than the target value thereof and decreasing the output voltage and/or the duration of the pulsed laser diode current pulses when the measured value of the pulsed laser diode current is greater than the target value thereof; and
(e) repeating steps (b) through (d) of this claim.

22. The method of claim 21 further comprising:
(a) establishing a target value for an output of the laser diode;
(b) measuring the value of the output of the laser diode;
(c) comparing the measured value of the output of the laser diode to the target value thereof,
(d) increasing the duration of the pulsed laser diode current pulses when the measured value of the output of the laser diode is less than the target value thereof and decreasing the duration of the pulsed laser diode current pulses when the measured or computed value of the output of the laser diode is greater than the target value thereof; and
(e) repeating steps (b) through (d) of this claim.

23. The method of claim 22 further comprising:
determining a power consumption by computing power consumption of the laser diode or computing power drawn from a power source;
storing the power consumption when the most recently determined value thereof is less than a previously stored value thereof; and
changing the duration of the pulsed laser diode current pulses in a direction to further decrease the determined power consumption.

24. The method of claim 19 wherein the laser diode includes:
a semiconductor laser diode; or
a green semiconductor laser diode; or
a blue semiconductor laser diode; or
a light emitting diode.
